(19) United States
(12) Patent Application Publication
(10) Pub. No.: US 2024/0094287 A1
(43) Pub. Date: Mar. 21, 2024

(54) LOW POWER ENVIRONMENT FOR HIGH PERFORMANCE PROCESSOR WITHOUT LOW POWER MODE

(71) Applicant: ADVANTEST CORPORATION, Tokyo (JP)

(72) Inventors: Edmundo De La Puente, San Jose, CA (US); Linden Hsu, San Jose, CA (US); Mei-Mei Su, San Jose, CA (US); Marilyn Kushnick, San Jose, CA (US)

(21) Appl. No.: 18/229,965

(22) Filed: Aug. 3, 2023

Related U.S. Application Data
(60) Provisional application No. 63/407,074, filed on Sep. 15, 2022.
(60) Provisional application No. 63/440,597, filed on Jan. 23, 2023.

(51) Int. Cl. G01R 31/317; G01R 31/3183

(52) U.S. Cl. CPC G01R 31/31721; G01R 31/318307

(57) ABSTRACT

A tester system includes a test computer system for coordinating and controlling testing of a plurality of devices under test (DUTs) and a hardware interface module coupled to the test computer system and controlled by the test computer system, the hardware interface module operable to apply test input signals to the plurality of DUTs and operable to receive test output signals from the plurality of DUTs. The hardware interface module includes a memory for storing instructions and data, a high performance processor coupled to the memory, the high performance processor operable to perform testing functionality at high speed for application of test signals to the plurality of DUTs, the high performance processor operable to perform the testing functionality under control of instructions and data from the memory and under control from software commands from the test computer system, wherein further the high performance processor is not natively capable of low power mode operation. The test system also includes a low power module coupled to and external to the high performance processor, the low power module capable of operating in at least one low power mode, the high performance processor for directing the low power module to configure the plurality of DUTs into at least one low power mode and further for testing the plurality of DUTs using commands and data in low power. The test system further includes driver hardware for applying the commands and data in low power to the plurality of DUTs which are configured for low power operation during the testing.

### RELATED APPLICATION

This application claims benefit of, and priority to U.S. Provisional Patent Application 63/407,074 (Attorney Docket ATSY-0109-00.00US), filed Sep. 15, 2022, to De La Puente et al. This application claims benefit of, and priority to U.S. Provisional Patent Application 63/440,597 (Attorney Docket ATSY-0109-01.01US), filed Jan. 23, 2023, to De La Puente et al. This Application is related to U.S. patent application Ser. No. 13/773,569, now U.S. Pat. No. 10,162,007, filed Feb. 21, 2013. This Application is also related to U.S. patent application Ser. No. 15/914,553, now U.S. Pat. No. 11,009,550, filed Mar. 7, 2018. In addition, this Application is related to U.S. patent application Ser. No. 15/982,910, now U.S. Pat. No. 10,288,681, filed May 17, 2018. This Application is further related to U.S. patent application Ser. Nos. 17/135,731 and 17/135,790, filed Dec. 28, 2020. All such applications are hereby incorporated herein by reference in their entireties.

### FIELD OF INVENTION

Embodiments of the present invention relate to the field of manufacturing and test of electronics. More specifically, embodiments of the present invention relate to systems and methods for a low power environment for high performance processors that lack support for low power mode.

### BACKGROUND

Automated test equipment (ATE) can be any testing assembly that performs a test on a semiconductor device or electronic assembly. ATE assemblies may be used to execute automated tests that quickly perform measurements and generate test results that can then be analyzed. An ATE assembly may comprise a complex automated test assembly that may include a custom, dedicated computer control system and many different test instruments that are capable of automatically testing electronics parts and/or semiconductor wafer testing, such as system-on-chip (SOC) testing, integrated circuit testing, network interfaces, and/or solid state drives (SSDs). ATE systems both reduce the amount of time spent on testing devices to ensure that the device functions as designed and serve as a diagnostic tool to determine the presence of faulty components within a given device before it reaches the consumer.

Testing of Devices Under Test (DUTs) generally comprises sending a series of test patterns or “vectors” to stimulate a device, and collecting the device's responses. For complex assemblies, e.g., network interfaces, Universal Serial Bus (USB) adapters, and/or SSDs, such test patterns may take the form of high-level instructions, e.g., “read” or “write,” sector addresses, and “data.” Under the conventional art, patterns and workloads used to test device have been generated in hardware using an Algorithmic Pattern Generator (APG) and a hardware accelerator. For example, a hardware-based APG would generate a pattern of data, send an instruction to, e.g., an SSD, to write the data to a particular address or range of addresses, and read back the data. The APG would typically collect performance data on the transaction, and compare the written data to the received data to detect errors. This allowed the test systems to generate data at maximum speed of the DUT where the tester did not become the bottleneck.

In addition, under the conventional art, many DUTs operate on a standard “peripheral” interface, for example, Serial Attached SCSI (SAS), Serial AT Attachment (SATA), Serial Peripheral Interface (SPI), Inter-Integrated Circuit (I2C), Universal Serial Bus (USB), and the like. Such interfaces typically require conversion electronics from a more general purpose “main” or “processor” bus, e.g., Peripheral Component Interconnect Express (PCIe).

These designs were typically implemented in a Field-Programmable Gate Array (FPGA) to achieve faster time to market and design flexibility.

Commensurate with their increasing performance, more and computer peripherals are abandoning specialized bus interfaces and adopting “main” bus interfaces, e.g., PCIe. For example, high performance SSDs are migrating from serial AT attachment (SATA) interfaces to “M.2” PCIe interfaces. The FPGAs used in the conventional art testers are incapable of keeping up with the increased data rates required for testing of such emerging devices, and the FPGAs are further challenged to implement main bus protocols, e.g., PCIe “Generation 5” and/or PCIe CXL.

Newer ATE systems may employ high performance processor(s) in place of the above-described FPGAs to generate patterns, instructions, and/or workloads to test DUTs. Such high performance processors may be known as or referred to as “server,” “workstation,” “High Core Count (HCC),” and/or “enterprise” processors. One example of such a processor is the Intel® Xeon® “Sapphire Rapids” family of processors. Such high performance processors are generally necessary to achieve the data generation and data transfer rates required to test multiple, high-end devices under test (DUTs). Unfortunately, such high performance processors generally lack support for low power modes for “main” bus interfaces, e.g., PCIe. For example, the target systems for high performance processors are optimized for performance, and generally do not implement low power modes. However, for DUTs that implement low power modes, testing of such low power modes is of great importance.

### SUMMARY OF THE INVENTION

Therefore, what is needed are systems and methods in testers for low power environment for high performance processors that lack support for low power mode. What is additionally needed are tester systems and test methods for low power environment for high performance processors that lack support for low power mode that are able to test devices implementing low power modes. There is a further need for systems and methods for low power environment for high performance processors that lack support for low power mode that are compatible and complementary with existing systems and methods of testing electronic devices.

In accordance with an embodiment of the present invention, a tester system includes a test computer system for coordinating and controlling testing of a plurality of devices under test (DUTs) and a hardware interface module coupled to the test computer system and controlled by the test computer system, the hardware interface module operable to apply test input signals to the plurality of DUTs and operable to receive test output signals from the plurality of DUTs. The hardware interface module includes a memory for storing instructions and data, a high performance processor coupled to the memory, the high performance processor operable to perform testing functionality at high speed for application of test signals to the plurality of DUTs, the high performance processor operable to perform the testing functionality under control of instructions and data from the memory and under control from software commands from the test computer system, wherein further the high performance processor is not natively capable of low power mode operation. The test system also includes a low power module coupled to and external to the high performance processor, the low power module capable of operating in at least one low power mode, the high performance processor for directing the low power module to configure the plurality of DUTs into at least one low power mode and further for testing the plurality of DUTs using commands and data in low power. The test system further includes driver hardware for applying the commands and data in low power to the plurality of DUTs which are configured for low power operation during the testing.

Embodiments include the above and further include wherein the high performance processor is a high core count (HCC) processor.

Embodiments include the above and further include wherein the HCC processor comprises between 16 and 32 cores.

Embodiments include the above and further include wherein the HCC processor comprises N number of cores and wherein N is scalable based on a prescribed testing performance.

Embodiments include the above and further include wherein the instructions stored in the memory are programmable by the computer system and wherein further the instructions control operation of the high performance processor.

In accordance with a method embodiment of the present invention, a method of testing a plurality of devices under test (DUTs) while in low power mode includes coordinating and controlling testing of the plurality of devices under test (DUTs) using a computer system, and configuring the plurality of DUTs into low power mode, applying low power test signals to the plurality of DUTs and receiving low power output test signals from the plurality of DUTs. The configuring, the applying and the receiving are performed by a hardware interface module and further include using a high performance processor in communication with the computer system to automatically generate test vectors for testing the plurality of DUTs, wherein the test vectors are generated under control from the computer system and wherein further the high performance processor is not natively capable of low power mode operation; and using a low power module external to the high performance processor, and coupled between the high performance processor and the plurality of DUTs, to configure the plurality of DUTs in low power mode, to provide the low power test signals to the plurality of DUTs and to receive the low power output test signals from the plurality of DUTs for testing thereof in the low power mode.

Embodiments include the above and further include wherein the high performance processor is a high core count (HCC) processor

Embodiments include the above and further include wherein the HCC processor comprises between 16 and 32 cores.

Embodiments include the above and further include wherein the HCC processor comprises N number of cores and wherein N is scalable based on a prescribed testing performance.

Embodiments include the above and further include wherein the plurality of DUTs are ASIC devices.

Embodiments include the above and further include wherein the plurality of DUTs are memory devices.

### BRIEF DESCRIPTION OF THE DRAWINGS

The accompanying drawings, which are incorporated in and form a part of this specification, illustrate embodiments of the invention and, together with the description, serve to explain the principles of the invention. Unless otherwise noted, the drawings may not be drawn to scale.

FIG. 1 illustrates an exemplary block diagram of an exemplary system for low power environment for high performance processor without low power mode, in accordance with embodiments of the present invention.

FIG. 2 illustrates exemplary L1.1 and L2.2 enable conditions for a test system, in accordance with embodiments of the present invention.

FIG. 3 illustrates exemplary timing for L1.1 exit, in accordance with embodiments of the present invention.

FIG. 4 illustrates exemplary control of the clock signal REFCLK going in and out of the L1 sub-states, in accordance with embodiments of the present invention.

FIG. 5 illustrates an exemplary low power mode control logic, in accordance with embodiments of the present invention.

FIG. 6 illustrates an exemplary method of testing a plurality of devices under test (DUTs) while in low power mode, in accordance with embodiments of the present invention.

FIG. 7 illustrates a block diagram of an exemplary electronic system, which may be used as a platform to implement and/or as a control system for embodiments of the present invention.

### DETAILED DESCRIPTION

Reference will now be made in detail to various embodiments of the invention, examples of which are illustrated in the accompanying drawings. While the invention will be described in conjunction with these embodiments, it is understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the invention, numerous specific details are set forth in order to provide a thorough understanding of the invention. However, it will be recognized by one of ordinary skill in the art that the invention may be practiced without these specific details. In other instances, well known methods, procedures, components, and circuits have not been described in detail as not to unnecessarily obscure aspects of the invention.

Some portions of the detailed descriptions which follow (e.g., method 600) are presented in terms of procedures, steps, logic blocks, processing, and other symbolic representations of operations on data bits that may be performed on computer memory. These descriptions and representations are the means used by those skilled in the data processing arts to most effectively convey the substance of their work to others skilled in the art. A procedure, computer executed step, logic block, process, etc., is here, and generally, conceived to be a self-consistent sequence of steps or instructions leading to a desired result. The steps are those requiring physical manipulations of physical quantities. Usually, though not necessarily, these quantities take the form of electrical or magnetic signals capable of being stored, transferred, combined, compared, and otherwise manipulated in a computer system. It has proven convenient at times, principally for reasons of common usage, to refer to these signals as bits, values, elements, symbols, characters, terms, numbers, data, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present invention, discussions utilizing terms such as “applying” or “controlling” or “generating” or “testing” or “heating” or “bringing” or “capturing” or “storing” or “reading” or “analyzing” or “resolving” or “accepting” or “selecting” or “determining” or “displaying” or “presenting” or “computing” or “sending” or “receiving” or “reducing” or “detecting” or “setting” or “accessing” or “placing” or “forming” or “mounting” or “removing” or “ceasing” or “stopping” or “coating” or “processing” or “performing” or “adjusting” or “creating” or “executing” or “continuing” or “indexing” or “translating” or “calculating” or “measuring” or “gathering” or “running” or the like, refer to the action and processes of, or under the control of, a computer system, or similar electronic computing device, that manipulates and transforms data represented as physical (electronic) quantities within the computer system's registers and memories into other data similarly represented as physical quantities within the computer system memories or registers or other such information storage, transmission or display devices.

The meaning of “non-transitory computer-readable medium” should be construed to exclude only those types of transitory computer-readable media which were found to fall outside the scope of patentable subject matter under 35 U.S.C. § 101 in In re Nuijten, 500 F.3d 1346, 1356-57 (Fed. Cir. 2007). The use of this term is to be understood to remove only propagating transitory signals per se from the claim scope and does not relinquish rights to all standard computer-readable media that are not only propagating transitory signals per se.

In the following descriptions, various elements and/or features of embodiments in accordance with the present invention are presented in isolation so as to better illustrate such features and as not to unnecessarily obscure aspects of the invention. It is to be appreciated, however, that such features, e.g., as disclosed with respect to a first drawing, may be combined with other features disclosed in other drawings in a variety of combinations. All such embodiments are anticipated and considered, and may represent embodiments in accordance with the present invention.

Exemplary embodiments in accordance with the present invention are generally presented herein as relating to a Peripheral Component Interconnect Express (PCIe) computer expansion bus standard. It is to be appreciated that embodiments in accordance with the present invention are not limited to the illustrated PCIe embodiments. Rather, embodiments in accordance with the present invention are well suited to use with a wide range of other well-known computer expansion busses, including, for example, Compute Express Link (CXL), InfiniBand, RapidlO, HyperTransport, Intel QuickPath Interconnect, VMEbus (ANSI/IEEE 1014-1987), and/or Mobile Industry Processor Interface (MIPI), and such embodiments are considered within the scope of the present invention.

Low Power Environment for High Performance Processor without Low Power Mode

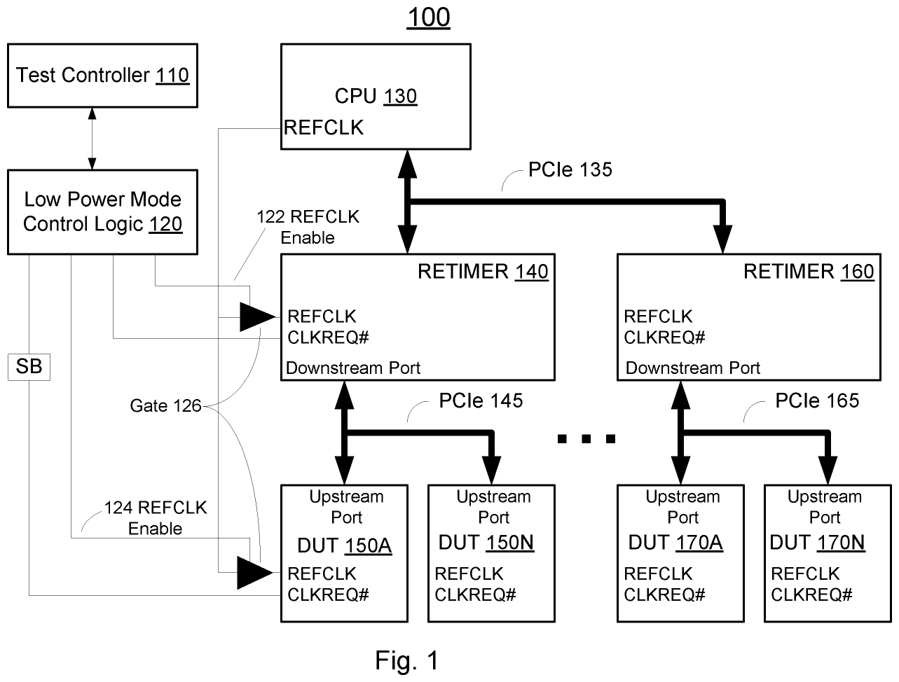

FIG. 1 illustrates an exemplary block diagram of an exemplary system 100 for low power environment for high performance processor without low power mode, in accordance with embodiments of the present invention. Test system 100 comprises a test controller 110, which may be, for example, a general-purpose computer system with special programming for the test application. Test system 100 also comprises a CPU 130. CPU 130 may comprise bus, e.g., PCIe, support components, including additional integrated circuit devices, in some embodiments. CPU 130 may be known as or referred to as “server,” “workstation,” “High Core Count (HCC),” and/or “enterprise” processors. One example of such a processor is the Intel® Xeon® “Sapphire Rapids” family of processors. CPU 130 may comprise 16 to 32 cores, in some embodiments. In some embodiments, CPU 130 may comprise more than 32 cores. For example, processors comprising 56 cores are currently available. In some embodiments, the number of cores in CPU 130 may be scalable, or selected, based on a prescribed testing performance.

CPU 130 is coupled to memory 132. Memory 132 may comprise high bandwidth memory (HBM), in some embodiments. Memory 132 may be coupled to CPU 130 in any well-known manner. For example, memory 132 may be directly coupled to CPU 130, memory 132 may be coupled to CPU 130 via a “chip set,” and/or memory 132 may be coupled to CPU 130 via bus 135.

CPU 130 is functionally coupled to PCIe bus 135. CPU 130, or other associated bus control components, may generate a signal REFCLK, in some embodiments. In some embodiments, REFCLK may be provided by other sources, e.g., a clock module, as is known for a variety of PCIe embodiments.

The PCIe standard specifies a 100 MHz clock (REFCLK) with at least ±300 ppm frequency stability for Generation 1, 2, 3 and 4, and at least ±100 ppm frequency stability for Generation 5, at both the transmitting and receiving devices. As will be further discussed below, REFCLK plays an important role in PCIe low power modes.

CPU 130 is coupled via PCIe bus 135 to a plurality of retimers, e.g., retimers 140, 160. The number of retimers illustrated is exemplary. In general, PCIe retimers are signal conditioning devices that actively participate in the PCIe protocol to facilitate communication between a root complex, e.g., PCIe bus 135, and an endpoint, e.g., PCIe bus 145. By providing improved signal integrity in a system, retimers increase the maximum allowable PCIe trace length and allow for more flexibility in system design. Exemplary retimers may include the PT5161L PCI Express® Retimer, commercially available from Astera Labs, Santa Clara, California, USA.

The retimer 140 produces PCIe bus 145, which functionally mirrors PCIe bus 135. For example, devices coupled to PCIe bus 145 are functionally coupled to devices on PCIe bus 135, e.g., CPU 130. Similarly, retimer 160 produces PCIe bus 165, which functionally mirrors PCIe bus 135.

A plurality of devices under test (DUTs), e.g., DUT 150A to DUT 150N, are coupled to PCIe bus 145. Similarly, a devices under test (DUTs), e.g., DUT 150A to DUT 150N, are coupled to PCIe bus 165. In some embodiments, eight DUTs may be coupled to a single CPU, e.g., CPU 130. In some embodiments, additional CPUs may be coupled to additional retimers and additional DUTs in a similar manner as illustrated in FIG. 1. For example, in a two CPU embodiment, there may be four retimers, e.g., two per CPU, and 16 DUTs, e.g., eight per CPU.

CPU 130 is configured, e.g., via software, to test the electrical and functional performance and characteristics of a device under test, e.g., DUT 150A. For example, CPU generates data and commands to be sent to a DUT, and receives results from the DUT.

In an exemplary Solid State Drive (SSD) DUT embodiment, CPU 130 may issue a “write” command to a SSD DUT, via PCIe bus 135. The CPU 130 may send, or write, a large amount of data to the SSD to be saved by the SSD. The CPU 130 may generate the data via an algorithm, or algorithmic pattern generator (APG) software operating on the CPU 130, in some embodiments. In some embodiments, the CPU 130 may access the data from a computer readable media, e.g., DRAM, coupled to the CPU 130. The CPU 130 will typically issue a “read” command to the SSD to read back the data previously written. In some embodiments, the CPU 130 may cause data to be sent and/or received directly from/to a memory to/from a DUT, e.g., via direct memory access (DMA). The CPU 130 may compare the data sent to the SSD with the data received from the SSD to confirm correct operation and/or to determine erroneous operation of the SSD.

In some embodiments, test system 100 may also perform electrical, power, and/or environmental testing on the plurality of DUTs. Such testing is known in the MPT3000ARC test system, commercially available from Advantest America, Inc., of San Jose, California, USA.

Test system 100 is well-suited to testing any device that is adapted to operate on the main bus, e.g., a PCIe bus. Such exemplary devices may include, for example, SSDs, DRAM modules, interfaces to rotating media, e.g., optical drives and magnetic hard drives (HDDs), RAID (Redundant Array of Independent Disks) controllers, network interface cards (NICs), including LAN, e.g., WIFI, wide area network (WAN), and/or fiber-optic interconnects, graphics cards, sound cards, modems, scanners, video capture cards, USB interfaces, Secure Digital (SD) Card interfaces, TV tuners, and the like.

PCIe Generation 5 has implemented what is known as or referred to as “L1 sub-states” to its power control regime. A new function is added to the PCIe pin “CLKREQ #” to provide a signaling protocol. This allows the PCIe transceivers to turn off their high-speed circuits and rely on the new signaling to wake them up again. Two new sub-states were defined: L1.1 and L1.2 providing their own power vs. exit latency trade-off choices. The L1.1 sub-state is intended for resumption times on the order of 20 microseconds (5 to 10 times longer than the L1 state allowed), while the L1.2 sub-state targets times on the order of 100 microseconds (up to 50 times longer than allowed for L1). Both L1.1 and L1.2 permit the PCIe transceivers to turn off their phase locked loops (PLLs) along with their receivers and transmitters, while L1.2 allows turning off common mode keeper circuits.

To implement the L1.1 and/or the L1.2 low power states, both the “upstream” and “downstream” ports may monitor the logical state of the CLKREQ # signal. It is appreciated that CPU 130 does not support the L1 low power sub-states (L1.1, L1.2). CPU 130 is not illustrated as accessing the CLKREQ # signal/pin. Hence, CPU 130 cannot natively support the L1.1 and/or L1.2 low power modes. However, a wide range of computer peripheral devices want to take advantage of the L1 low power sub-states. For example, such devices are intended for use in systems for which power consumption is important, e.g., in laptop computer systems. In order to test these modes, test system 100 comprises low power mode control logic 120.

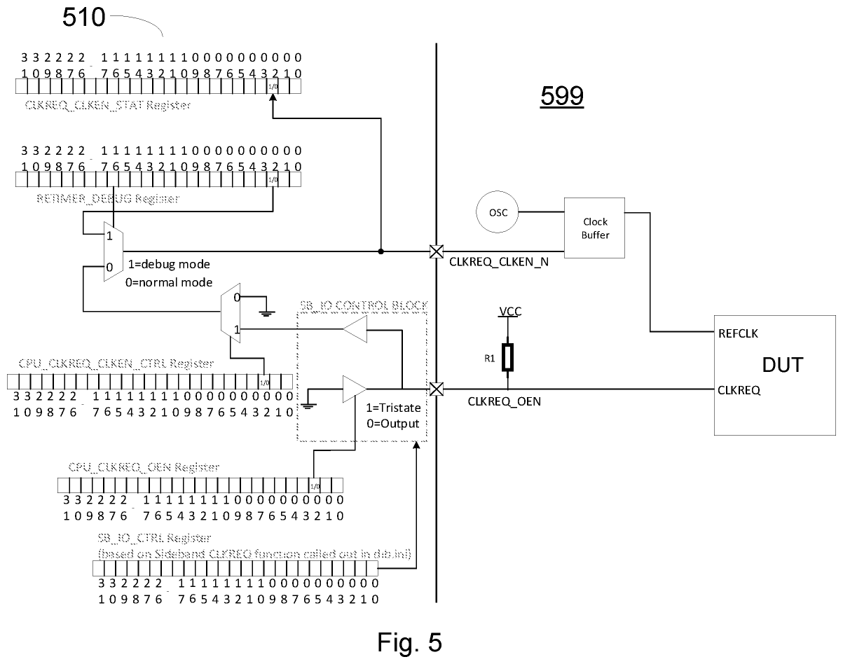

Low power mode control logic 120 exists separately from CPU 130, and may be controlled by test controller 110, in some embodiments. Low power mode control logic 120 functions to control the reference clock REFCLK in response to the CLKREQ # signal. Low power mode control logic 120 comprises storage locations, e.g., register bits, to indicate whether the L1 sub-states are enabled. These registers are further described with respect to FIG. 5, below. If the L1.1 state is enabled and the L1.2 state is not enabled, low power mode control logic 120 will respond to deassertion of the CLKREQ # signal by disabling the REFCLK using and by disabling Electrical Idle detect circuits. Any device on the PCIe bus, e.g., retimer 140 and/or DUT 150A, may request a L1 sub-state low power mode by deasserting CLKREQ #. In some embodiments, test controller 110 may command low power mode control logic 120 to enter a L1 sub-state low power mode by deasserting CLKREQ #. In response to the deassertion of CLKREQ #, low power mode control logic 120 will deassert signals 122 and 124 REFCLK enable, which will turn off gates 126, and not allow the REFCLK signal to propagate to the devices, e.g., retimer 140 and/or DUT 150A. In some embodiments, gates 126 may be tri-state buffers.

If the L1.2 enable bit is set, the L1.2 sub-state is entered in response to deassertion of the CLKREQ # signal.

Test system 100 may perform a variety of tests and/or measurements related to a DUT entering and exiting a low power mode. For example, test system 100 may measure power consumption while a DUT is in low power mode. Test system 100 may also measure latency for a DUT to come out of low power mode(s) until the DUT is partially and/or fully functional. It is appreciated that CPU 130 may not implement and/or execute a variety of low power modes while testing a plurality of DUTs. For example, CPU 130 may be required to execute instructions and/or perform other operations while a DUT is in low power mode.

Under the conventional art, DUTs were coupled to a hardware bus adapter socket which converted a main computer expansion bus, e.g., PCIe, to a more specialized peripheral bus, e.g., Universal Serial Bus (USB), Serial Attached SCSI (SAS), and/or Serial AT Attachment (SATA) etc., as used by the DUT. In accordance with embodiments of the present invention, a DUT is coupled to a main computer expansion bus, e.g., PCIe.

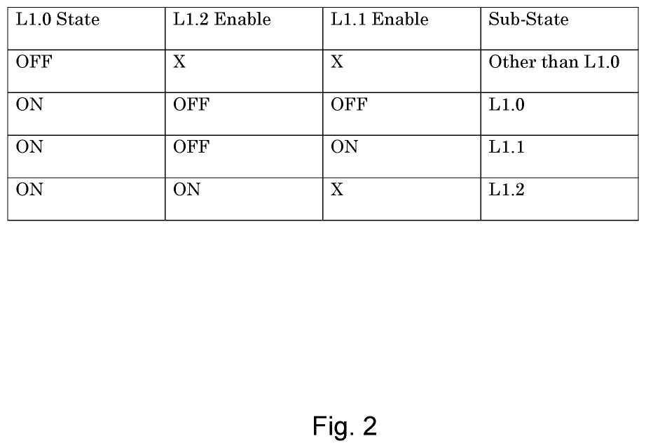

FIG. 2 illustrates exemplary L1.1 and L2.2 enable conditions for test system 100, in accordance with embodiments of the present invention. The L1.1 and L1.2 enable bits are not contained within CPU 130 as envisioned by the PCIe standard. Rather, these bits are contained within low power mode control logic 120, in accordance with embodiments of the present invention.

The Link is considered to be in PCI-PM (PCI Bus Power Management Interface Specification) L1.0 when the L1 PM Sub-state is L1.0 and the LTSSM (Link Training and Status State Machine) entered L1 through PCI-PM compatible power management. The Link is considered to be in ASPM (Active State Power Management) state L1.0 when the L1 PM Sub-state is in L1.0 and LTSSM entered L1 through ASPM.

The following rules define how the L1.1 and L1.2 sub-states are entered:
Both the Upstream and Downstream Ports may monitor the logical state of the CLKREQ # signal.
When in PCI-PM L1.0 and the PCI-PM L1.2 Enable bit is Set, the L1.2 sub-state may be entered when CLKREQ # is deasserted.
When in PCI-PM L1.0 and the PCI-PM L1.1 Enable bit is Set, the L1.1 sub-state may be entered when CLKREQ # is deasserted and the PCI-PM L1.2 Enable bit is Clear.
When in ASPM L1.0 and the ASPM L1.2 Enable bit is Set, the L1.2 sub-state may be entered when CLKREQ # is deasserted and all of the following conditions are true:
   The reported snooped LTR value last sent or received by this Port is greater than or equal to the value set by the LTR L1.2 THRESHOLD Value and Scale fields, or there is no snoop service latency requirement.
   The reported non-snooped LTR last sent or received by this Port value is greater than or equal to the value set by the LTR L1.2 THRESHOLD Value and Scale fields, or there is no non-snoop service latency requirement.
When in ASPM L1.0 and the ASPM L1.1 Enable bit is Set, the L1.1 sub-state may be entered when CLKREC # is deasserted and the conditions for entering the L1.2 sub-state are not satisfied.

When the entry conditions for L1.2 are satisfied, the following rules apply:
Both the Upstream and Downstream Ports may monitor the logical state of the CLKREQ #input signal.
An Upstream Port may not deassert CLKREQ #until the Link has entered L1.0.
It is permitted for either Port to assert CLKREQ # to prevent the Link from entering L1.2.
Downstream Port intending to block entry into L1.2 may assert
CLKREQ #before the Link enters L1 When CLKREQ # is deasserted the Ports enter the L1.2.Entry sub-state of L1.2.

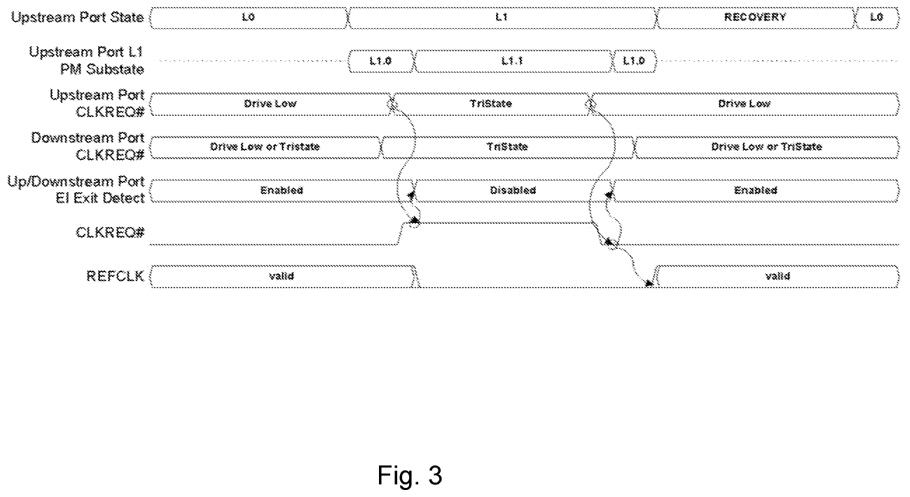

FIG. 3 illustrates exemplary timing for L1.1 exit, in accordance with embodiments of the present invention. If either the Upstream or Downstream Port needs to initiate exit from L1.1, it may assert CLKREQ #until the Link exits Recovery. The Upstream Port may assert CLKREQ # on entry to Recovery, and may continue to assert CLKREQ #until the next entry into g, or other state allowing CLKREQ #deassertion.
Next state is L1.0 (L1) if CLKREQ # is asserted.
The REFCLK will eventually be turned on as defined in the PCI Express Mini CEM spec, which may be delayed according to the LTR advertised by the Upstream Port.

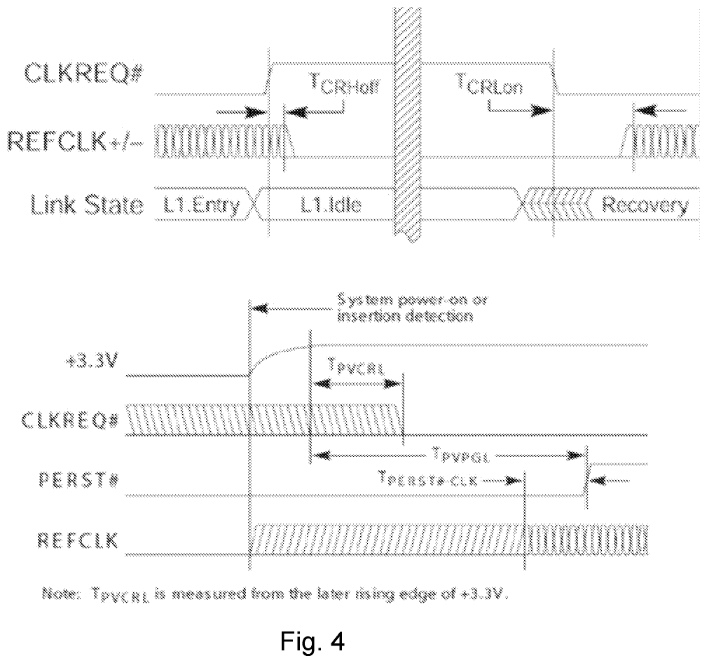

FIG. 4 illustrates exemplary control of the clock signal REFCLK going in and out of the L1 sub-states, in accordance with embodiments of the present invention. Whenever the upstream link enters L1 link state, it shall allow its reference clock to be turned off by deasserting CLKREQ #. To exit, the device may assert CLKREQ # to re-enable REFCLK.

FIG. 5 illustrates an exemplary low power mode control logic 510, in accordance with embodiments of the present invention. Low power mode control logic 510 may be equivalent to low power mode control logic (FIG. 1), in some embodiments. FIG. 5 also illustrates additional circuitry 599 that is outside of low power mode control logic 510, in some embodiments.

Low power mode control logic 510 allows CLKREQ from a DUT, e.g., DUT 150A as described in FIG. 1, to enable/disable the clock signal REFCLK. Low power mode control logic 510 also enables CLKREQ OEN to force a DUT into low power state.

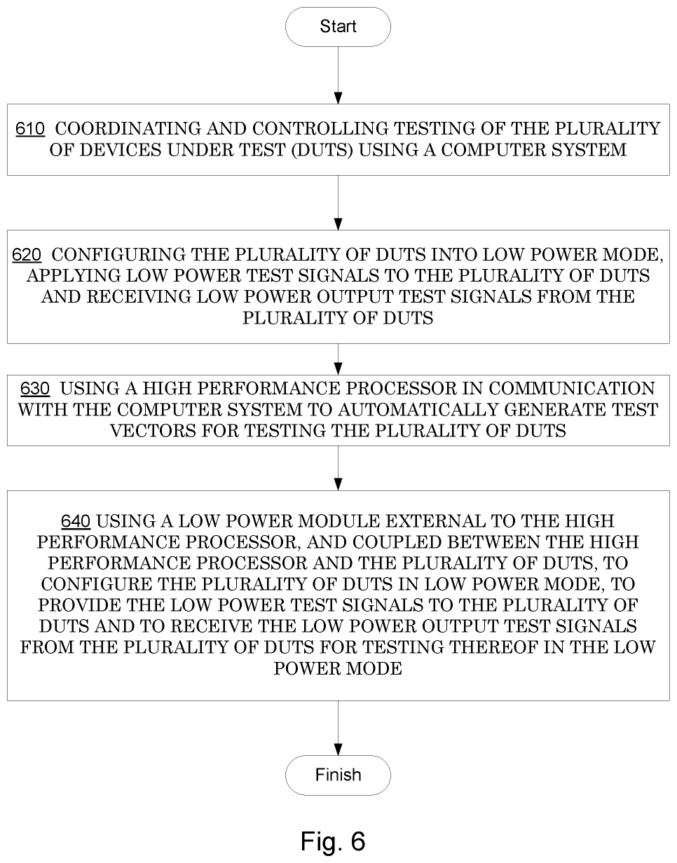

FIG. 6 illustrates an exemplary method 600 of testing a plurality of devices under test (DUTs) while in low power mode, in accordance with embodiments of the present invention. In 610, testing of the plurality of devices under test (DUTs) is coordinated and controlled using a computer system.

In 620, the plurality of DUTs are configured into low power mode, and low power test signals are applied to the plurality of DUTs and receiving low power output test signals from the plurality of DUTs. The configuring, the applying, and the receiving are performed by a hardware interface module.

In 630, a high performance processor in communication with the computer system automatically generates test vectors for testing the plurality of DUTs. The test vectors are generated under control from the computer system and wherein further the high performance processor is not natively capable of low power mode operation.

In 640, the plurality of DUTs are configured in low power mode using a low power module external to the high performance processor, and coupled between the high performance processor and the plurality of DUTs. The low power module provides the low power test signals to the plurality of DUTs and receives the low power output test signals from the plurality of DUTs for testing thereof in the low power mode.

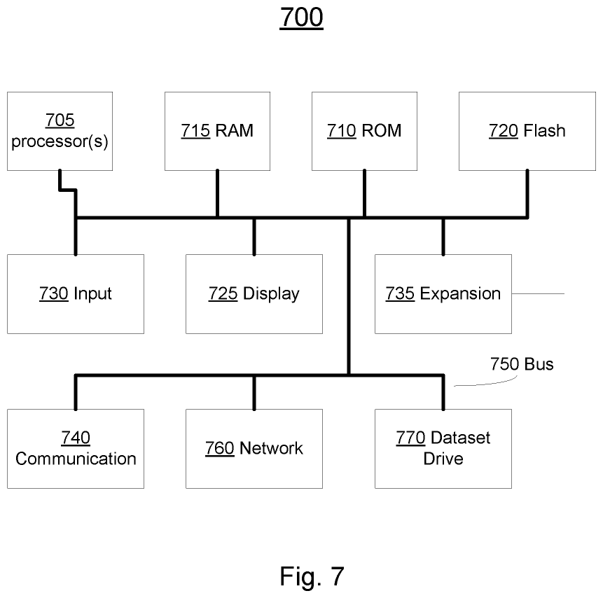

FIG. 7 illustrates a block diagram of an exemplary electronic system 700, which may be used as a platform to implement and/or as a control system, e.g., system controller 110 and/or CPU 130, as described in FIG. 1, for embodiments of the present invention. Electronic system 700 may be a “server” computer system, in some embodiments. Electronic system 700 includes an address/data bus 750 for communicating information, a central processor complex 705 functionally coupled with the bus for processing information and instructions. Bus 750 may comprise, for example, a Peripheral Component Interconnect Express (PCIe) computer expansion bus, industry standard architecture (ISA), extended ISA (EISA), MicroChannel, Multibus, IEEE 796, IEEE 1196, IEEE 1496, PCI, Computer Automated Measurement and Control (CAMAC), MBus, Runway bus, Compute Express Link (CXL), and the like.

Central processor complex 705 may comprise a single processor or multiple processors, e.g., a multi-core processor, or multiple separate processors, in some embodiments. Central processor complex 705 may comprise various types of well-known processors in any combination, including, for example, digital signal processors (DSP), graphics processors (GPU), complex instruction set (CISC) processors, reduced instruction set (RISC) processors, and/or very long word instruction set (VLIW) processors. In some embodiments, exemplary central processor complex 705 may comprise a finite state machine, for example, realized in one or more field programmable gate array(s) (FPGA), which may operate in conjunction with and/or replace other types of processors to control embodiments in accordance with the present invention.

Electronic system 700 may also include a volatile memory 715 (e.g., random access memory RAM) coupled with the bus 750 for storing information and instructions for the central processor complex 705, and a non-volatile memory 710 (e.g., read only memory ROM) coupled with the bus 750 for storing static information and instructions for the processor complex 705. Electronic system 700 also optionally includes a changeable, non-volatile memory 720 (e.g., NOR flash) for storing information and instructions for the central processor complex 705 which can be updated after the manufacture of system 700. In some embodiments, only one of ROM 710 or Flash 720 may be present.

Also included in electronic system 700 of FIG. 7 is an optional input device 730. Device 730 can communicate information and command selections to the central processor 700. Input device 730 may be any suitable device for communicating information and/or commands to the electronic system 700. For example, input device 730 may take the form of a keyboard, buttons, a joystick, a track ball, an audio transducer, e.g., a microphone, a touch sensitive digitizer panel, eyeball scanner, and/or the like.

Electronic system 700 may comprise a display unit 725. Display unit 725 may comprise a liquid crystal display (LCD) device, cathode ray tube (CRT), field emission device (FED, also called flat panel CRT), light emitting diode (LED), plasma display device, electro-luminescent display, electronic paper, electronic ink (e-ink) or other display device suitable for creating graphic images and/or alphanumeric characters recognizable to the user. Display unit 725 may have an associated lighting device, in some embodiments.

Electronic system 700 also optionally includes an expansion interface 735 coupled with the bus 750. Expansion interface 735 can implement many well known standard expansion interfaces, including without limitation the Secure Digital Card interface, universal serial bus (USB) interface, Compact Flash, Personal Computer (PC) Card interface, CardBus, Peripheral Component Interconnect (PCI) interface, Peripheral Component Interconnect Express (PCI Express), mini-PCI interface, IEEE 1394, Small Computer System Interface (SCSI), Personal Computer Memory Card International Association (PCMCIA) interface, Industry Standard Architecture (ISA) interface, RS-232 interface, and/or the like. In some embodiments of the present invention, expansion interface 735 may comprise signals substantially compliant with the signals of bus 750.

A wide variety of well-known devices may be attached to electronic system 700 via the bus 750 and/or expansion interface 735. Examples of such devices include without limitation rotating magnetic memory devices, flash memory devices, digital cameras, wireless communication modules, digital audio players, and Global Positioning System (GPS) devices.

System 700 also optionally includes a communication port 740. Communication port 740 may be implemented as part of expansion interface 735. When implemented as a separate interface, communication port 740 may typically be used to exchange information with other devices via communication-oriented data transfer protocols. Examples of communication ports include without limitation RS-232 ports, universal asynchronous receiver transmitters (UARTs), USB ports, infrared light transceivers, ethernet ports, IEEE 1394, and synchronous ports.

System 700 optionally includes a network interface 760, which may implement a wired or wireless network interface. Electronic system 700 may comprise additional software and/or hardware features (not shown) in some embodiments.

Various modules of system 700 may access computer readable media, and the term is known or understood to include removable media, for example, Secure Digital (“SD”) cards, CD and/or DVD ROMs, diskettes and the like, as well as non-removable or internal media, for example, hard drives, solid state drive s (SSD), RAM, ROM, flash, and the like.

Embodiments in accordance with the present invention provide systems and methods for low power environment for high performance processors that lack support for low power mode. In addition, embodiments in accordance with the present invention provide systems and methods for low power environment for high performance processors that lack support for low power mode that are able to test devices implementing low power modes. Further, embodiments in accordance with the present invention provide systems and methods for for low power environment for high performance processors that lack support for low power mode that are compatible and complementary with existing systems and methods of testing electronic devices.

Although the invention has been shown and described with respect to a certain exemplary embodiment or embodiments, equivalent alterations and modifications will occur to others skilled in the art upon the reading and understanding of this specification and the annexed drawings. In particular regard to the various functions performed by the above described components (assemblies, devices, etc.) the terms (including a reference to a “means”) used to describe such components are intended to correspond, unless otherwise indicated, to any component which performs the specified function of the described component (e.g., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more features of the other embodiments as may be desired and advantageous for any given or particular application.

Various embodiments of the invention are thus described. While the present invention has been described in particular embodiments, it should be appreciated that the invention should not be construed as limited by such embodiments, but rather construed according to the below claims.

What is claimed is:

1. A tester system comprising:
a test computer system for coordinating and controlling testing of a plurality of devices under test (DUTs); and
a hardware interface module coupled to said test computer system and controlled by said test computer system, said hardware interface module operable to apply test input signals to said plurality of DUTs and operable to receive test output signals from said plurality of DUTs, said hardware interface module comprising:
a memory for storing instructions and data;
a high performance processor coupled to said memory, said high performance processor operable to perform testing functionality at high speed for application of test signals to said plurality of DUTs, said high performance processor operable to perform said testing functionality under control of instructions and data from said memory and under control from software commands from said test computer system, wherein further said high performance processor is not natively capable of low power mode operation;
a low power module coupled to and external to said high performance processor, said low power module capable of operating in at least one low power mode, said high performance processor for directing said low power module to configure said plurality of DUTs into at least one low power mode and further for testing said plurality of DUTs using commands and data in low power; and
driver hardware for applying said commands and data in low power to said plurality of DUTs which are configured for low power operation during said testing.

2. The tester system as described in claim 1 wherein said high performance processor is a high core count (HCC) processor.

3. The tester system as described in claim 2 wherein said HCC processor comprises between 16 and 32 cores.

4. The tester system as described in claim 2 wherein said HCC processor comprises N number of cores and wherein N is scalable based on a prescribed testing performance.

5. The tester system as described in claim 1 wherein said instructions stored in said memory are programmable by said computer system and wherein further said instructions control operation of said high performance processor.

6. A method of testing a plurality of devices under test (DUTs) while in low power mode, said method comprising:
coordinating and controlling testing of said plurality of devices under test (DUTs) using a computer system; and
configuring said plurality of DUTs into low power mode, applying low power test signals to said plurality of DUTs and receiving low power output test signals from said plurality of DUTs, wherein said configuring, said applying and said receiving are performed by a hardware interface module and further comprise:
using a high performance processor in communication with said computer system to automatically generate test vectors for testing said plurality of DUTs, wherein said test vectors are generated under control from said computer system and wherein further said high performance processor is not natively capable of low power mode operation; and
using a low power module external to said high performance processor, and coupled between said high performance processor and said plurality of DUTs, to configure said plurality of DUTs in low power mode, to provide said low power test signals to said plurality of DUTs and to receive said low power output test signals from said plurality of DUTs for testing thereof in said low power mode.

7. The method of testing as described in claim 6 wherein said high performance processor is a high core count (HCC) processor

8. The method of testing as described in claim 7 wherein said HCC processor comprises between 16 and 32 cores.

9. The method of testing as described in claim 7 wherein said HCC processor comprises N number of cores and wherein N is scalable based on a prescribed testing performance.

10. The method of testing as described in claim 6 wherein said plurality of DUTs are ASIC devices.

11. The method of testing as described in claim 6 wherein said plurality of DUTs are memory devices.

12. An electronic circuit comprising:
a register comprising a plurality of bits to indicate permission status for a plurality of low power modes; and
control logic configured to gate off a clock signal to other components responsive to receipt of a request for at least one of the plurality of low power modes and the permission status for at least one of the plurality of low power modes.

13. The electronic circuit of claim 12 configured to implement a plurality of low power modes for a system, wherein said system comprises a host processor that does not implement at least one of the plurality of low power modes.

14. The electronic circuit of claim 12 wherein the plurality of low power modes for a system comprises a PCIe L1.1 low power sub-state.

15. The electronic circuit of claim 14 wherein the plurality of low power modes for a system comprises a PCIe L1.2 low power sub-state.

16. An automated test equipment (ATE) system comprising:
a test computer system for coordinating and controlling testing of a plurality of devices under test (DUTs);
a memory for storing instructions and data coupled to said test computer system;
a high performance processor coupled to said memory, said high performance processor operable to perform testing functionality at high speed for application of test signals to said plurality of DUTs based on instructions stored in said memory,
wherein said high performance processor is not natively capable of controlling all low power modes of said plurality of DUTs; and
a low power module coupled to and external to said high performance processor, said low power module configured to control said plurality of DUTs into said all low power modes of said plurality of DUTs.

17. The ATE system of claim 16 wherein said plurality of DUTs are coupled to a PCIe bus.

18. The ATE system of claim 17 wherein said low power module is configured to control a PCIe L1.1 low power sub-state.

19. The ATE system of claim 17 wherein said low power module is configured to control a PCIe L1.2 low power sub-state.

20. A non-transitory computer-readable medium having instructions stored thereon that, responsive to execution by an electronic system, cause said electronic system to perform operations to test a plurality of devices under test (DUTs) while in low power mode, the operations comprising:
coordinating and controlling testing of said plurality of devices under test (DUTs) using a computer system; and
configuring said plurality of DUTs into low power mode, applying low power test signals to said plurality of DUTs and receiving low power output test signals from said plurality of DUTs, wherein said configuring, said applying and said receiving are performed by a hardware interface module and further comprise:
using a high performance processor in communication with said computer system to automatically generate test vectors for testing said plurality of DUTs, wherein said test vectors are generated under control from said computer system and wherein further said high performance processor is not natively capable of low power mode operation; and
using a low power module external to said high performance processor, and coupled between said high performance processor and said plurality of DUTs, to configure said plurality of DUTs in low power mode, to provide said low power test signals to said plurality of DUTs and to receive said low power output test signals from said plurality of DUTs for testing thereof in said low power mode.
